(19) United States
(12) Patent Application Publication
(10) Pub. No.: US 2025/0300683 A1
(43) Pub. Date: Sep. 25, 2025

(54) PROGRAMMABLE AMPLIFIER TOPOLOGY

(71) Applicant: QUALCOMM Incorporated, San Diego, CA (US)

(72) Inventors: Xinmin YU, San Diego, CA (US); Chirag Dipak PATEL, San Diego, CA (US)

(21) Appl. No.: 18/610,466

(22) Filed: Mar. 20, 2024

(51) Int. Cl. H04B 1/04; H03F 3/24

(52) U.S. Cl. CPC H04B 1/0458; H03F 3/245; H03F 2200/294; H03F 2200/451; H04B 2001/0416

(57) ABSTRACT

In some aspects, a programmable amplifier may comprise an n-channel metal-oxide-semiconductor (NMOS) amplification path and a complementary metal-oxide-semiconductor (CMOS) amplification path. In some aspects, the NMOS amplification path may include a first NMOS transistor and a second NMOS transistor that are connected in parallel between an input and an output. In some aspects, the CMOS amplification path may include a p-channel metal-oxide-semiconductor (PMOS) transistor connected in parallel with the first NMOS transistor between the input and the output. In some aspects, the programmable amplifier may further comprise a plurality of switches that are programmable to switch the PMOS transistor off in a first mode, such as an NMOS mode or a high linearity mode, and to switch the second NMOS transistor off in a second mode, such as a CMOS mode or a low current mode. Numerous other aspects are described.

### FIELD OF THE DISCLOSURE

Aspects of the present disclosure generally relate to wireless receivers and wireless transmitters and, for example, a programmable amplifier topology that is reconfigurable between a high linearity mode and a low current or low power mode.

### BACKGROUND

Amplifiers are commonly used in various electronic devices or communications systems to provide signal amplification (e.g., increasing an amplitude of a signal). Different amplifier types are available for different uses. For example, a wireless communications device (e.g., a cellular phone) may include a transmitter and a receiver for bi-directional communication. The receiver may use a low noise amplifier (LNA), while the transmitter may use a power amplifier (PA). Additionally, or alternatively, the receiver and the transmitter may use variable gain amplifiers (VGAs).

### SUMMARY

In some aspects, a programmable amplifier includes an n-channel metal-oxide-semiconductor (NMOS) amplification path that includes a first NMOS transistor and a second NMOS transistor that are connected in parallel between an input and an output; a complementary metal-oxide-semiconductor (CMOS) amplification path that includes a p-channel metal-oxide-semiconductor (PMOS) transistor connected in parallel with the first NMOS transistor between the input and the output; and a plurality of switches that are programmable to switch the PMOS transistor off in a first mode and to switch the second NMOS transistor off in a second mode.

In some implementations, a method includes configuring, at a first time, a plurality of switches to drive a load in a circuit using an NMOS amplification path that includes a first NMOS transistor and a second NMOS transistor that are connected in parallel between an input and an output of the circuit; and configuring, at a second time, the plurality of switches to drive the load in the circuit using a CMOS amplification path that includes a PMOS transistor connected in parallel with the first NMOS transistor between the input and the output of the circuit.

In some implementations, a circuit includes a first NMOS transistor in a first amplification path; a PMOS transistor in a second amplification path; a second NMOS transistor in the first amplification path and the second amplification path; and a plurality of switches that are programmable to switch the PMOS transistor off in an NMOS mode and to switch the first NMOS transistor off in a CMOS mode.

Aspects generally include an apparatus, a method, a system, a wireless communication device, a transceiver, a transmitter, a receiver, an amplifier, and/or a circuit, as substantially described with reference to and as illustrated by the drawings and specification.

The foregoing has outlined rather broadly the features and technical advantages of examples according to the disclosure in order that the detailed description that follows may be better understood. Additional features and advantages will be described hereinafter. The conception and specific examples disclosed may be readily utilized as a basis for modifying or designing other structures for carrying out the same purposes of the present disclosure. Such equivalent constructions do not depart from the scope of the appended claims. Characteristics of the concepts disclosed herein, both their organization and method of operation, together with associated advantages will be better understood from the following description when considered in connection with the accompanying figures. Each of the figures is provided for the purposes of illustration and description, and not as a definition of the limits of the claims.

### BRIEF DESCRIPTION OF THE DRAWINGS

So that the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects. The same reference numbers in different drawings may identify the same or similar elements.

FIG. 1 is a diagram illustrating examples of amplifier topologies in a wireless receiver or a wireless transmitter, in accordance with the present disclosure.

FIGS. 2A-2C are diagrams illustrating examples associated with a programmable amplifier topology, in accordance with the present disclosure.

FIG. 3 is a diagram illustrating a flowchart of an example process associated with a programmable amplifier topology, in accordance with the present disclosure.

FIG. 4 is a diagram illustrating an example design of a wireless device, in accordance with the present disclosure.

### DETAILED DESCRIPTION

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. One skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

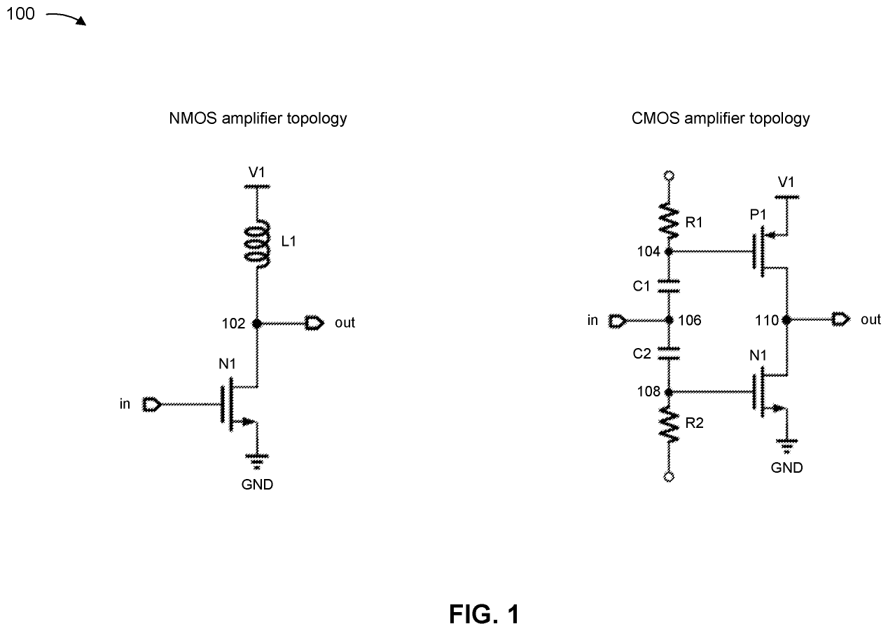

FIG. 1 is a diagram illustrating examples 100 of amplifier topologies that may be used in a wireless receiver or a wireless transmitter, in accordance with the present disclosure. As shown in FIG. 1, examples 100 include an n-channel metal-oxide-semiconductor (NMOS) topology, or a common source topology, that may provide a high linearity, and a complementary metal-oxide-semiconductor (CMOS) topology that may provide a low current and/or a low power consumption.

For example, as shown in FIG. 1, the NMOS topology includes an NMOS transistor N1 with a source connected to ground, a gate connected to an input (e.g., for receiving a signal to be amplified), and a drain connected to a node 102. As further shown in FIG. 1, the NMOS topology includes an inductor L1 coupled between a voltage supply V1 (e.g., Vdd) and node 102, which is connected to an output (e.g., for outputting the amplified signal). Accordingly, the NMOS topology provides full headroom from the voltage supply V1 to ground, which provides the NMOS topology with a very high linearity (e.g., the NMOS topology effectively has no headroom limitation for expected signal inputs in some configurations).

As further shown in FIG. 1, the CMOS topology includes an NMOS transistor N1 and a p-channel metal-oxide-semiconductor (PMOS) transistor P1, where the PMOS transistor P1 includes a source connected to a voltage supply V1, a gate connected to a node 104, and a drain connected to a node 110 that is coupled to an output. As further shown, the NMOS transistor N1 includes a source connected to ground, a gate connected to node 108, and a drain connected to node 110. As further shown, the CMOS topology includes an input coupled to node 106, a first capacitor C1 coupled between node 104 and node 106, a first resistor R1 coupled to node 104, a second capacitor C2 coupled between node 106 and node 108, and a second resistor R2 coupled to node 108. Accordingly, the NMOS transistor N1 and the PMOS transistor P1 may reuse current, which helps to reduce power consumption (e.g., relative to the NMOS topology). However, because the NMOS transistor N1 and the PMOS transistor P1 are stacked under the same voltage supply V1, each transistor receives half the supply voltage, whereby the voltage headroom at the output limits linearity in the CMOS topology. In some cases, a switchable supply can be used in the CMOS topology to improve the linearity. However, a switchable supply requires two sets of supply bypass capacitors, and may also impose risks in terms of reliability.

Accordingly, as described herein, an amplifier in a wireless receiver or a wireless transmitter (e.g., a power amplifier (PA), a low noise amplifier (LNA), a last stage amplifier, or the like) typically includes either the NMOS topology or the CMOS topology depending on one or more design requirements associated with the amplifier. For example, in cases where an amplifier is designed for use as a last stage amplifier in a signal path of a wireless receiver (e.g., a final stage intermediate frequency (IF) amplifier in a heterodyne receiver), the amplifier may need to drive a load (e.g., a 50 ohm load) with a gain that satisfies (e.g., equals or exceeds) a threshold and with a high linearity and a low power consumption. In another example, some wireless communication systems (e.g., New Radio (NR), which may also be referred to as 5G, or subsequent generations of radio access technologies, such as 6G and beyond) impose strict linearity and high gain specifications on a receive signal path, even when a received signal is a desired signal that is free of jammers (e.g., due to the much wider signal bandwidths utilized in 5G wireless communication systems). Consequently, non-linearity affecting the desired signal can limit throughput in some cases (e.g., where throughput should be at a highest level). However, there are also use cases where high linearity is not specified (e.g., a low power mode), but increased gain may still be specified. An example of such a use case includes a quadrature phase shift keying (QPSK) mode or during a wake-up mode of a receiver when a very low signal is being received and when reducing power consumption is a primary optimization parameter.

Although the NMOS topology may satisfy the high linearity requirement, when applicable, the NMOS topology is associated with a high current that may fail to satisfy a low power consumption requirement. Furthermore, although the CMOS topology may provide a lower current (and therefore lower power consumption) than the NMOS topology, linearity is limited in the CMOS topology by the voltage headroom at the output. In other words, the NMOS topology may be preferable in some conditions (e.g., when a high linearity is needed), and the CMOS topology may be preferable in other conditions (e.g., when a low current or low power consumption is needed), whereby implementing one topology or the other may result in undesirable performance (e.g., low linearity or high power consumption) in certain circumstances. Accordingly, neither the NMOS topology nor the CMOS topology are suitable for balancing tradeoffs between linearity and current consumption requirements in a wireless receiver or a wireless transmitter in such circumstances, because the NMOS topology is associated with a relatively higher power consumption than the CMOS topology and the CMOS topology is associated with a relatively lower linearity than the NMOS topology.

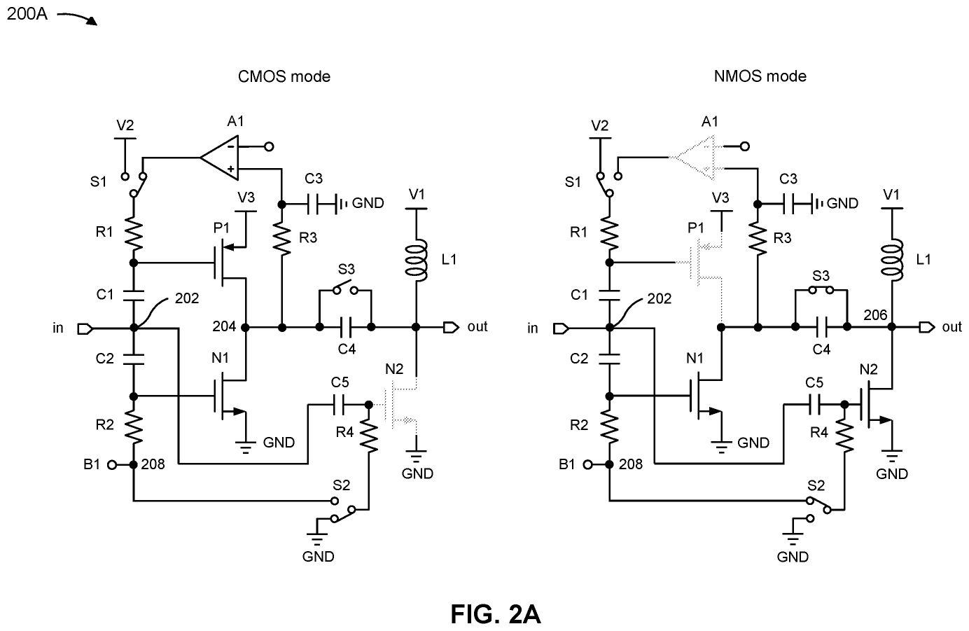

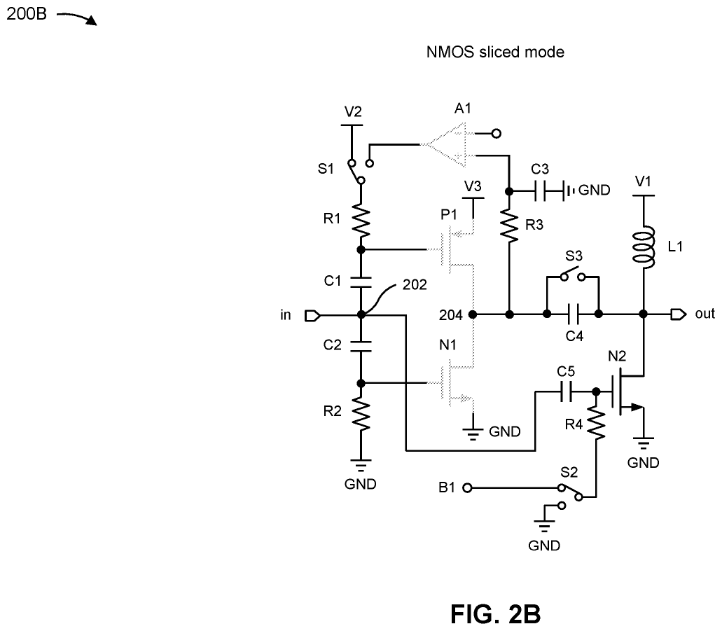

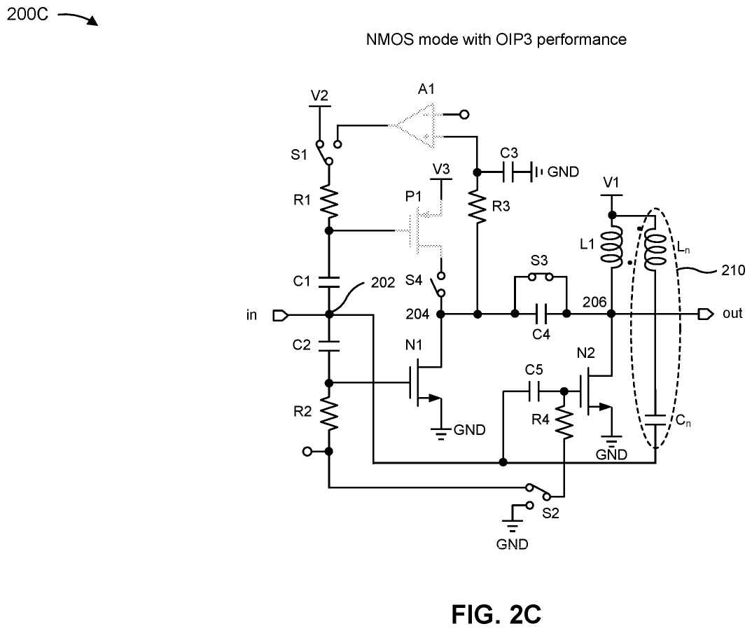

Various aspects described herein generally relate to an amplifier with a topology that can be programmed or otherwise reconfigured between an NMOS mode and a CMOS mode. For example, as shown in FIGS. 2A-2C and described in further detail herein, the amplifier topology may include an NMOS amplification path with two NMOS amplifying transistors arranged in parallel, with one NMOS transistor also paired with a PMOS amplifying transistor in a CMOS amplification path. In some aspects, the NMOS amplification path and the CMOS amplification path may be coupled to a common input and a common output. In some aspects, the amplifier topology further includes various switches that may be programmed or otherwise configured to turn off the NMOS amplifying transistor that is not included in the CMOS amplification path when the amplifier is configured in the CMOS mode (e.g., to provide a lower current or lower power consumption), or to turn off the PMOS amplifying transistor that is included in the CMOS amplification path when the amplifier topology is configured in the NMOS mode (e.g., to provide a higher linearity). In some aspects, the amplifier topology may include a selectable PMOS bias that is used in the CMOS mode and a separately selectable NMOS bias that is used in the NMOS mode. In some aspects, the second NMOS amplifying transistor (that is not included in the CMOS amplification path) may be selectably grounded (e.g., by a switch). In some aspects, the amplifier topology may be included in a millimeter wave integrated circuit (mmW-IC), such as a last amplifier in a receive path before a signal (e.g., that was previously downconverted, prior to the amplifier, to an IF or baseband signal) is output to a cable or wire (e.g., for communication to a transceiver or another component of a wireless device). In this way, the amplifier may be dynamically programmed to operate in an NMOS or high linearity mode or in a CMOS or low current and/or low power consumption mode at different times.

As indicated above, FIG. 1 is provided as an example. Other examples may differ from what is described with regard to FIG. 1.

FIGS. 2A-2C are diagrams illustrating examples 200A, 200B, 200C associated with a programmable amplifier topology, in accordance with the present disclosure. In some aspects, example 200A illustrates an amplifier topology that may be configured in a CMOS mode to satisfy a low current or a low power consumption requirement or an NMOS mode to satisfy a high linearity requirement. Furthermore, example 200B illustrates an NMOS sliced mode that may be used to provide a linearity that is higher than the CMOS mode for a similar (e.g., same) current used in the NMOS mode, and example 200C illustrates additional circuit components that may be included in the amplifier to provide a higher linearity with output third-order intercept point (OIP3) performance.

More particularly, as shown in FIG. 2A, the programmable or reconfigurable amplifier topology may include a first NMOS transistor N1, a second NMOS transistor N2, and a PMOS transistor P1, where the first NMOS transistor N1 and the second NMOS transistor N2 may be connected in parallel between an input and an output in an NMOS amplification path. Furthermore, as shown, the PMOS transistor P1 may be connected in parallel with the first NMOS transistor N1 between the input and the output in a CMOS amplification path. As further shown in FIG. 2A, the programmable or reconfigurable amplifier topology may include various switches, S1, S2, S3, that may be programmable to switch the second NMOS transistor N2 off in the CMOS mode and to switch the PMOS transistor P1 off in the NMOS mode. In addition, as shown in FIG. 2A and described herein, the programmable or reconfigurable amplifier topology may include an amplifier A1, a plurality of resistors R1-R4, a plurality of capacitors C1-C5, an inductor L1, a plurality of voltage supplies V1-V3, and a plurality of nodes 202-208.

For example, as shown in FIG. 2A, a first switch S1 may be coupled between the amplifier A1 and the resistor R1 in the CMOS mode or between the voltage supply V2 and the resistor R1 in the NMOS mode. As further shown in FIG. 2A, a second switch S2 may be coupled between the resistor R4 and ground in the CMOS mode or between the resistor R3 and the resistor R2 in the NMOS mode. As further shown in FIG. 2A, a third switch S3 may be provided across the capacitor C4, and the third switch S3 may be open in the CMOS mode or closed in the NMOS mode. In this way, in the CMOS mode, the second NMOS transistor N2 may be selectably grounded and turned off, the input of the amplifier circuit may be connected to the PMOS transistor P1 via node 202, and the output of the amplifier circuit may be connected to the output from the CMOS amplification path, which is represented by node 204. Alternatively, in the NMOS mode, the amplifier A1 and the PMOS transistor P1 may be selectably turned off (e.g., by coupling switch S1 to voltage supply V2), the input of the amplifier circuit may be connected to the second NMOS transistor N2 via node 202, and the output of the amplifier circuit may be connected to the output from the NMOS amplification path, which is represented by node 206.

In some aspects, the CMOS amplification path and the NMOS amplification path may have separate biasing, which may be enabled by the inductor L1 and the capacitor C4. For example, in the CMOS mode, the CMOS amplification path does not need a connection to the voltage supply V1 and is instead biased by the PMOS transistor P1. For example, in the CMOS mode, a PMOS bias loop may be formed to control a gate of the PMOS transistor P1, where the PMOS bias loop may be formed from node 204 through the resistor R3, the amplifier A1, the switch S1, and the resistor R1 to the gate of the PMOS transistor P1. Furthermore, the capacitor C4 may be provided between node 204 and the voltage supply V1 such that node 204 is not connected to the voltage supply V1 when switch S3 is open in the CMOS mode (e.g., the capacitor C4 is an output capacitor that isolates the PMOS transistor P1 and the first NMOS transistor N1 from the voltage supply V1 in the CMOS mode). In the NMOS mode, however, the first NMOS transistor N1 and the second NMOS transistor N2 are connected to the voltage supply V1. For example, in the NMOS mode, the switch S3 may be closed in the NMOS mode such that the capacitor C4 is bypassed, and an NMOS bias for the NMOS amplification path includes the voltage supply V1 and the inductor L1, which are coupled to the first NMOS transistor N1 and the second NMOS transistor N2. In this way, both the first NMOS transistor N1 and the second NMOS transistor N2 may be used for amplification in the NMOS mode.

Accordingly, as described herein, the amplifier topology shown in FIG. 2A may provide a unified topology that is programmable between a low current or low power consumption mode and a high linearity mode. For example, in some aspects, the CMOS mode may consume less current than the NMOS mode, and may therefore provide lower power consumption than the NMOS mode, with a sufficient gain and a moderate linearity. The NMOS mode may consume a higher current than the CMOS mode to achieve an equivalent gain, and provides a higher linearity than the CMOS mode. Additionally, or alternatively, the current can be increased in the NMOS mode (e.g., by switching a supply voltage to a higher voltage) to provide a higher gain or otherwise satisfy a gain threshold without degrading linearity. In this way, the amplifier topology can be used in any suitable amplifier to dynamically switch, program, or otherwise reconfigure the amplifier between high linearity and low current modes. For example, as described herein, the various switches S1-S3 may be toggled to program the amplifier to drive a load in a signal path of a wireless receiver or a wireless transmitter according to a current requirement, a power consumption requirement, and/or a linearity requirement. For example, the various switches S1-S3 may be toggled to program the amplifier in the CMOS mode when a low current or low power consumption is desired, or to program the amplifier in the NMOS mode when a high linearity is desired.

As shown in FIG. 2B, the amplifier topology may be programmed to support a third configuration that corresponds to an NMOS sliced mode associated with a lower current than the NMOS mode and a higher linearity than the CMOS mode (e.g., the NMOS sliced mode may provide a moderate current, or moderate power savings relative to the NMOS mode, with a lower gain and a higher linearity than the CMOS mode). For example, as shown in FIG. 2B, the switch S3 across the output capacitor C4 may be open, which may turn off one branch of the NMOS amplification path. For example, in the NMOS sliced mode, the switch S3 may be open while the switch S1 is connected to voltage supply V2, the switch S2 is coupled between the resistor R4 and a bias voltage B1, and the resistor R2 is connected to ground. In some examples, the circuits shown in FIG. 2A and FIG. 2B may include one or more switches that are not explicitly shown to change the programming of the circuit between the CMOS mode, the NMOS, and the NMOS sliced mode. For example, one or more switches may be provided to connect the resistor R2 to node 208 in the CMOS mode or the NMOS mode and to connect the resistor R2 to ground in the NMOS sliced mode. In this case, the PMOS transistor P1 and the first NMOS transistor N1 that is included in the CMOS amplification path are switched off, and the amplifier A1 provided in the PMOS bias loop is switched off. In this way, the NMOS sliced mode may provide a lower gain and a better linearity than the CMOS mode, while using the same current as the CMOS mode. Accordingly, the various switches S1-S3 may be appropriately toggled to program the amplifier in the NMOS sliced mode when a moderate current or power consumption (e.g., a lower current or power consumption than the NMOS mode) is desired, when a moderate linearity (e.g., a higher linearity than the CMOS mode) is desired, and/or when a lower gain is tolerable. Alternatively, in some aspects, the switch S3 may be removed from the amplifier topology. However, removing the switch S3 may prevent from the first NMOS transistor N1 from being utilized in the NMOS mode (e.g., may limit the supported modes to only the CMOS mode shown in FIG. 2A and the NMOS sliced mode shown in FIG. 2B).

In some aspects, as shown in FIG. 2C, the amplifier topology may include additional circuit components to support a higher linearity (e.g., relative to the NMOS mode shown in FIG. 2A and/or the sliced NMOS mode shown in FIG. 2B). For example, in some aspects, the amplifier topology shown in FIG. 2C may provide an NMOS mode with a linearity that satisfies OIP3 performance criteria. For example, in telecommunications, a third-order intercept point (IP3) is a specific metric associated with third-order intermodulation distortion (IMD3), which is a measure for weakly nonlinear systems and/or devices (e.g., receivers, linear amplifiers, and/or mixers). For example, in some cases, the PMOS transistor P1 may impact linearity at the output of the amplifier even when the PMOS transistor P1 is switched off (e.g., by coupling the switch S1 to the voltage supply V2 and closing the switch S3 across the output capacitor C4). Accordingly, as shown in FIG. 2C, the programmable amplifier topology may include a fourth switch S4, which is coupled between a drain of the PMOS transistor and the output from the CMOS amplification path, which is represented by node 204. In particular, as shown in FIG. 2C, the switch S4 may be open in the NMOS mode to isolate an output of the NMOS application path, represented by node 206, from a nonlinear parasitic capacitance caused by the PMOS transistor P1 that is switched off in the NMOS mode (e.g., a nonlinear parasitic capacitance from a gate to a drain (Cgd) of the PMOS transistor P1). Furthermore, in cases where the switch S4 is included in the amplifier topology, the switch S4 may be closed in the CMOS mode. Additionally, or alternatively, the amplifier topology may include a neutralization circuit 210 arranged to neutralize a nonlinear parasitic capacitance associated with the first NMOS transistor N1 and/or the second NMOS transistor N2. For example, as shown in FIG. 2C, the neutralization circuit 210 may include an inductor Ln and a capacitor Cn, which may store energy corresponding to a nonlinear parasitic Cgd of the first NMOS transistor N1 and/or the second NMOS transistor N2. For example, as shown in FIG. 2C, the neutralization circuit 210 may be coupled between the voltage supply V1 and node 202. In this way, the amplifier topology shown in FIG. 2C may support an NMOS mode with OIP3 performance and a higher linearity than the NMOS mode shown in FIG. 2A.

As indicated above, FIG. 2 is provided as an example. Other examples may differ from what is described with regard to FIG. 2, and additional or fewer components may be included. In some examples, the components of the amplifier topologies described above are directly connected together, as respectively illustrated in FIGS. 2A-2C. In such configurations, there are no intervening components or elements (not illustrated) between the various components in the circuits.

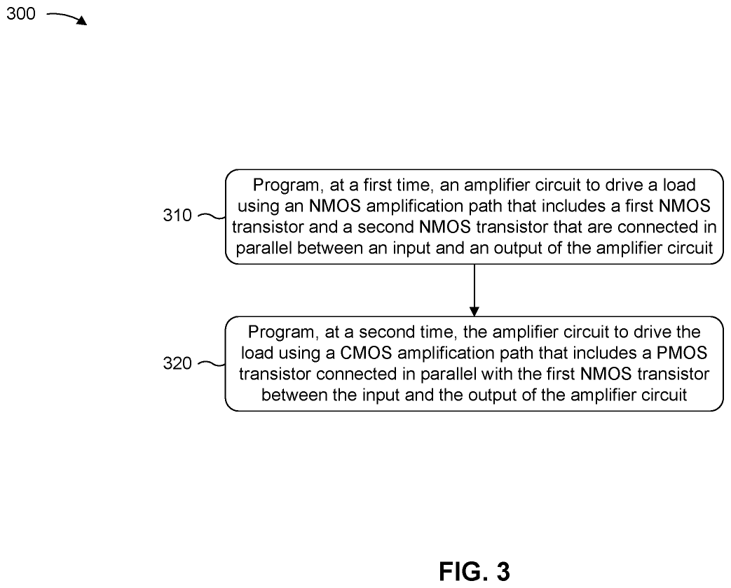

FIG. 3 is a diagram illustrating an example process 300 performed, for example, at a processor, controller, or the like or an apparatus of a processor, controller, or the like, in accordance with the present disclosure. Example process 300 is an example where the apparatus or the processor, controller, or the like performs operations associated with a programmable amplifier topology.

As shown in FIG. 3, in some aspects, process 300 may include configuring, at a first time, a plurality of switches to drive a load in a circuit using an NMOS amplification path that includes a first NMOS transistor and a second NMOS transistor that are connected in parallel between an input and an output of the circuit (block 310). For example, the processor, controller, or the like may configure, at a first time, a plurality of switches to drive a load in a circuit using an NMOS amplification path that includes a first NMOS transistor and a second NMOS transistor that are connected in parallel between an input and an output of the circuit, as described above.

As further shown in FIG. 3, in some aspects, process 300 may include configuring, at a second time, the plurality of switches to drive the load in the circuit using a CMOS amplification path that includes a PMOS transistor connected in parallel with the first NMOS transistor between the input and the output of the circuit (block 320). For example, the processor, controller, or the like may configure, at a second time, the plurality of switches to drive the load in the circuit using a CMOS amplification path that includes a PMOS transistor connected in parallel with the first NMOS transistor between the input and the output of the circuit, as described above.

Process 300 may include additional aspects, such as any single aspect or any combination of aspects described below and/or in connection with one or more other processes described elsewhere herein.

In a first aspect, the plurality of switches are configured to drive the load using the NMOS amplification path at the first time based at least in part on a high linearity requirement at the first time.

In a second aspect, alone or in combination with the first aspect, the plurality of switches are configured to drive the load using the CMOS amplification path at the second time based at least in part on a low current requirement or a low power consumption requirement at the second time.

In a third aspect, alone or in combination with one or more of the first and second aspects, process 300 includes configuring, at a third time, the plurality of switches to drive the load in the circuit using the NMOS amplification path with the first NMOS transistor switched off.

In a fourth aspect, alone or in combination with one or more of the first through third aspects, the plurality of switches includes a switch, across an output capacitor, that is closed at the first time and open at the second time.

Although FIG. 3 shows example blocks of process 300, in some aspects, process 300 may include additional blocks, fewer blocks, different blocks, or differently arranged blocks than those depicted in FIG. 3. Additionally, or alternatively, two or more of the blocks of process 300 may be performed in parallel.

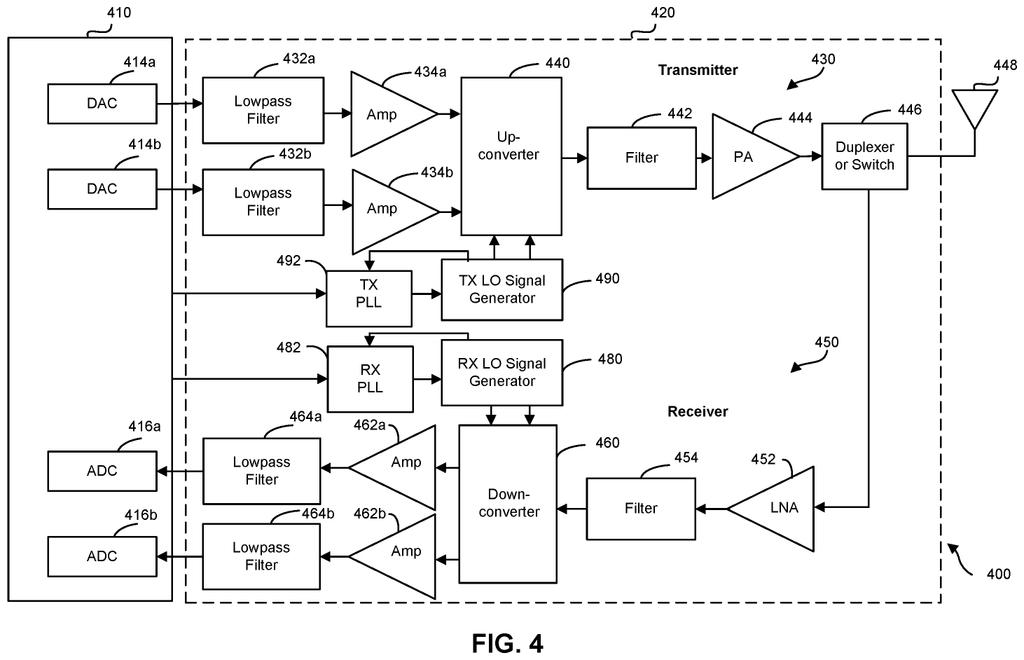

FIG. 4 is a diagram illustrating an example design of a wireless device 400, in accordance with the present disclosure. As shown in FIG. 4, the wireless device 400 includes baseband circuits 410 for sending, receiving, and processing baseband digital signals to and from a transceiver 420. The transceiver 420 sends and receives radio frequency (RF) communication signals to and from one or more antennas 448. For example, as shown in FIG. 4, the transceiver 420 includes a transmitter 430 and a receiver 450 that support bi-directional communication. In general, the wireless device 400 may include any number of transmitters and any number of receivers for any number of communication systems and frequency ranges.

A transmitter or a receiver may be implemented with a super-heterodyne architecture or a direct-conversion architecture. In the super-heterodyne architecture, a signal is frequency converted between RF and baseband in multiple stages (e.g., from RF to an IF in one stage, and then from the IF to baseband in another stage for a receiver). In the direct-conversion architecture, a signal is frequency converted between RF and baseband in one stage. The super-heterodyne and direct-conversion architectures may use different circuit blocks and/or have different requirements.

In the transmit path, digital communication signals are converted to analog signals by digital-to-analog converters (DACs) 414a and 414b and coupled to a transmitter 430, where “a” and “b” channels may correspond to in-phase (I) and quadrature (Q) components of the signal. Within the transmitter 430, lowpass filters 432a and 432b filter the analog I and Q components of the signal, respectively, to remove undesired images caused by the prior digital-to-analog conversion. Amplifiers 434a and 434b amplify the signals from the lowpass filters 432a and 432b, respectively, and provide I and Q baseband signals. An upconverter 440 upconverts the I and Q baseband signals with I and Q transmit (TX) local oscillating (LO) signals from a TX LO signal generator 490 and provides an upconverted signal. A filter 442 filters the upconverted signal to remove undesired images caused by the frequency upconversion as well as noise in a receive frequency range. A PA 444 amplifies the signal from filter 442 to obtain the desired output power level and provides a transmit RF signal. The transmit RF signal is routed through a duplexer or switch 446 and transmitted via an antenna 448.

In the receive path, antenna 448 receives signals and provides a received RF signal, which is routed through duplexer or switch 446 and provided to an LNA 452. The received RF signal is amplified by the LNA 452 and filtered by a filter 454 to obtain a desired RF input signal. A downconverter 460 downconverts the RF input signal with I and Q receive (RX) LO signals from an RX LO signal generator 480 and provides I and Q baseband signals. The I and Q baseband signals are amplified by amplifiers 462a and 462b and further filtered by lowpass filters 464a and 464b to obtain I and Q analog input signals, which are provided to analog-to-digital converters (ADCs) 416a and 416b in the baseband circuits 410.

In some aspects, the TX LO signal generator 490 generates the I and Q TX LO signals used for frequency upconversion. The RX LO signal generator 480 generates the I and Q RX LO signals used for frequency downconversion. Each LO signal is a periodic signal with a particular fundamental frequency. A TX phase lock loop (PLL) 492 receives timing information from the baseband circuits 410 and generates a control signal used to adjust the frequency and/or phase of the TX LO signals from TX LO signal generator 490. Similarly, an RX PLL 482 receives timing information from the baseband circuits 410 and generates a control signal used to adjust the frequency and/or phase of the RX LO signals from RX LO signal generator 480.

FIG. 4 shows an example transceiver design. In general, the conditioning of the signals in a transmitter and a receiver may be performed by one or more stages of amplifier, filter, upconverter, downconverter, or the like. These circuit blocks may be arranged differently from the configuration shown in FIG. 4. Furthermore, other circuit blocks not shown in FIG. 4 may also be used to condition the signals in the transmitter and receiver. Some circuit blocks in FIG. 4 may also be omitted. All or a portion of the transceiver 420 may be implemented on one or more analog integrated circuits (ICs), RF ICs (RFICs), and/or mixed-signal ICs, among other examples.

In some aspects, the amplifiers 434a and 434b, the PA 444, the LNA 452, and/or the amplifiers 462a and 462b may include a programmable topology. For example, as described in more detail elsewhere herein, the programmable topology may include an NMOS amplification path that includes a first NMOS transistor and a second NMOS transistor that are connected in parallel between an input and an output; a CMOS amplification path that includes a PMOS transistor connected in parallel with the first NMOS transistor between the input and the output; and a plurality of switches that are programmable to switch the PMOS transistor off in a first mode and to switch the second NMOS transistor off in a second mode.

In some aspects, the baseband circuits 410, a processor, a controller, or another suitable component of the wireless device 400 may program or otherwise configure the amplifiers 434a and 434b, the PA 444, the LNA 452, and/or the amplifiers 462a and 462b to operate in an NMOS or high linearity mode or a CMOS or low current mode. For example, as described in more detail elsewhere herein, the baseband circuits 410, a processor, a controller, or another suitable component of the wireless device 400 may configure, at a first time, a plurality of switches to drive a load in a circuit using an NMOS amplification path that includes a first NMOS transistor and a second NMOS transistor that are connected in parallel between an input and an output of the circuit; and configure, at a second time, the plurality of switches to drive the load in the circuit using a CMOS amplification path that includes a PMOS transistor connected in parallel with the first NMOS transistor between the input and the output of the circuit. Additionally, or alternatively, the baseband circuits 410, a processor, a controller, or another suitable component of the wireless device 400 may perform one or more other operations described herein.

As indicated above, FIG. 4 is provided as an example. Other examples may differ from what is described with regard to FIG. 4.

The following provides an overview of some Aspects of the present disclosure:

Aspect 1: A programmable amplifier, comprising: an NMOS amplification path that includes a first NMOS transistor and a second NMOS transistor that are connected in parallel between an input and an output; a CMOS amplification path that includes a PMOS transistor connected in parallel with the first NMOS transistor between the input and the output; and a plurality of switches that are programmable to switch the PMOS transistor off in a first mode and to switch the second NMOS transistor off in a second mode.

Aspect 2: The programmable amplifier of Aspect 1, wherein the first mode is a high linearity mode and the second mode is a low current mode.

Aspect 3: The programmable amplifier of any of Aspects 1-2, wherein the plurality of switches are further programmable to switch the PMOS transistor and the first NMOS transistor off in a third mode.

Aspect 4: The programmable amplifier of Aspect 3, wherein the third mode is associated with one or more of a lower gain or a lower current than the first mode and a higher linearity than the second mode.

Aspect 5: The programmable amplifier of any of Aspects 1-4, further comprising: an NMOS bias that includes a voltage supply and an inductor coupled to the first NMOS transistor and the second NMOS transistor in the first mode; and an output capacitor arranged to isolate the PMOS transistor and the first NMOS transistor from the voltage supply in the second mode.

Aspect 6: The programmable amplifier of Aspect 5, wherein the plurality of switches includes a switch, across the output capacitor, that is closed in the first mode and open in the second mode.

Aspect 7: The programmable amplifier of any of Aspects 1-6, wherein the plurality of switches includes a switch, coupled between a drain of the PMOS transistor and an output of the CMOS amplification path, that is open in the first mode to isolate a nonlinear parasitic capacitance from the PMOS transistor that is switched off in the first mode.

Aspect 8: The programmable amplifier of any of Aspects 1-7, further comprising: a neutralization circuit arranged to neutralize a nonlinear parasitic capacitance from the first NMOS transistor and the second NMOS transistor in the first mode.

Aspect 9: The programmable amplifier of any of Aspects 1-8, wherein the plurality of switches are programmed to drive a load in a signal path of a wireless receiver according to one or more of a current requirement or a linearity requirement.

Aspect 10: The programmable amplifier of Aspect 1, wherein the signal path is included in or coupled to a mmW-IC.

Aspect 11: A method, comprising: configuring, at a first time, a plurality of switches to drive a load in a circuit using an NMOS amplification path that includes a first NMOS transistor and a second NMOS transistor that are connected in parallel between an input and an output of the circuit; and configuring, at a second time, the plurality of switches to drive the load in the circuit using a CMOS amplification path that includes a PMOS transistor connected in parallel with the first NMOS transistor between the input and the output of the circuit.

Aspect 12: The method of Aspect 11, wherein the plurality of switches are configured to drive the load using the NMOS amplification path at the first time based at least in part on a high linearity requirement or a low power consumption requirement at the first time.

Aspect 13: The method of any of Aspects 11-12, wherein the plurality of switches are configured to drive the load using the CMOS amplification path at the second time based at least in part on a low current requirement or a low power consumption requirement at the second time.

Aspect 14: The method of any of Aspects 11-13, further comprising: configuring, at a third time, the plurality of switches to drive the load in the circuit using the NMOS amplification path with the first NMOS transistor switched off.

Aspect 15: The method of any of Aspects 11-14, wherein the plurality of switches includes a switch, across an output capacitor, that is closed at the first time and open at the second time.

Aspect 16: A circuit, comprising: a first NMOS transistor in a first amplification path; a PMOS transistor in a second amplification path; a second NMOS transistor in the first amplification path and the second amplification path; and a plurality of switches that are programmable to switch the PMOS transistor off in an NMOS mode and to switch the first NMOS transistor off in a CMOS mode.

Aspect 17: The circuit of Aspect 16, further comprising: a neutralization circuit arranged to neutralize a nonlinear parasitic capacitance from the first NMOS transistor and the second NMOS transistor in the NMOS mode.

Aspect 18: The circuit of Aspect 17, wherein the plurality of switches are further programmable to switch the PMOS transistor and the second NMOS transistor off in a sliced NMOS mode.

Aspect 19: The circuit of Aspect 18, wherein the plurality of switches are programmable to drive a load in a signal path of a wireless receiver in the NMOS mode, the CMOS mode, or the sliced NMOS mode according to one or more of a current requirement or a linearity requirement.

Aspect 20: The circuit of Aspect 18, wherein the plurality of switches are programmable to drive a load in a signal path of a wireless receiver in the NMOS mode, the CMOS mode, or the sliced NMOS mode according to one or more of a current requirement or a linearity requirement.

Aspect 21: A system configured to perform one or more operations recited in one or more of Aspects 1-20.

Aspect 22: An apparatus comprising means for performing one or more operations recited in one or more of Aspects 1-20.

Aspect 23: A non-transitory computer-readable medium storing a set of instructions, the set of instructions comprising one or more instructions that, when executed by a device, cause the device to perform one or more operations recited in one or more of Aspects 1-20.

Aspect 24: A computer program product comprising instructions or code for executing one or more operations recited in one or more of Aspects 1-20.

The foregoing disclosure provides illustration and description but is not intended to be exhaustive or to limit the aspects to the precise forms disclosed. Modifications and variations may be made in light of the above disclosure or may be acquired from practice of the aspects.

As used herein, the term “component” is intended to be broadly construed as hardware and/or a combination of hardware and software. “Software” shall be construed broadly to mean instructions, instruction sets, code, code segments, program code, programs, subprograms, software modules, applications, software applications, software packages, routines, subroutines, objects, executables, threads of execution, procedures, and/or functions, among other examples, whether referred to as software, firmware, middleware, microcode, hardware description language, or otherwise. As used herein, a “processor” is implemented in hardware and/or a combination of hardware and software. It will be apparent that systems and/or methods described herein may be implemented in different forms of hardware and/or a combination of hardware and software. The actual specialized control hardware or software code used to implement these systems and/or methods is not limiting of the aspects. Thus, the operation and behavior of the systems and/or methods are described herein without reference to specific software code, since those skilled in the art will understand that software and hardware can be designed to implement the systems and/or methods based, at least in part, on the description herein.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

Even though particular combinations of features are recited in the claims and/or disclosed in the specification, these combinations are not intended to limit the disclosure of various aspects. Many of these features may be combined in ways not specifically recited in the claims and/or disclosed in the specification. The disclosure of various aspects includes each dependent claim in combination with every other claim in the claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Furthermore, as used herein, the terms “set” and “group” are intended to include one or more items and may be used interchangeably with “one or more.” Where only one item is intended, the phrase “only one” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. Also, as used herein, the term “or” is intended to be inclusive when used in a series and may be used interchangeably with “and/or,” unless explicitly stated otherwise (e.g., if used in combination with “either” or “only one of”).

What is claimed is:

1. A programmable amplifier, comprising:
an n-channel metal-oxide-semiconductor (NMOS) amplification path that includes a first NMOS transistor and a second NMOS transistor that are connected in parallel between an input and an output;
a complementary metal-oxide-semiconductor (CMOS) amplification path that includes a p-channel metal-oxide-semiconductor (PMOS) transistor connected in parallel with the first NMOS transistor between the input and the output; and
a plurality of switches that are programmable to switch the PMOS transistor off in a first mode and to switch the second NMOS transistor off in a second mode.

2. The programmable amplifier of claim 1, wherein the first mode is a high linearity mode and the second mode is a low current mode.

3. The programmable amplifier of claim 1, wherein the plurality of switches are further programmable to switch the PMOS transistor and the first NMOS transistor off in a third mode.

4. The programmable amplifier of claim 3, wherein the third mode is associated with one or more of a lower gain or a lower current than the first mode and a higher linearity than the second mode.

5. The programmable amplifier of claim 1, further comprising:
an NMOS bias that includes a voltage supply and an inductor coupled to the first NMOS transistor and the second NMOS transistor in the first mode; and
an output capacitor arranged to isolate the PMOS transistor and the first NMOS transistor from the voltage supply in the second mode.

6. The programmable amplifier of claim 5, wherein the plurality of switches includes a switch, across the output capacitor, that is closed in the first mode and open in the second mode.

7. The programmable amplifier of claim 1, wherein the plurality of switches includes a switch, coupled between a drain of the PMOS transistor and an output of the CMOS amplification path, that is open in the first mode to isolate a nonlinear parasitic capacitance from the PMOS transistor that is switched off in the first mode.

8. The programmable amplifier of claim 1, further comprising:
a neutralization circuit arranged to neutralize a nonlinear parasitic capacitance from the first NMOS transistor and the second NMOS transistor in the first mode.

9. The programmable amplifier of claim 1, wherein the plurality of switches are programmed to drive a load in a signal path of a wireless receiver according to one or more of a current requirement or a linearity requirement.

10. The programmable amplifier of claim 9, wherein the signal path is included in or coupled to a millimeter wave integrated circuit.

11. A method, comprising:
configuring, at a first time, a plurality of switches to drive a load in a circuit using an n-channel metal-oxide-semiconductor (NMOS) amplification path that includes a first NMOS transistor and a second NMOS transistor that are connected in parallel between an input and an output of the circuit; and
configuring, at a second time, the plurality of switches to drive the load in the circuit using a complementary metal-oxide-semiconductor (CMOS) amplification path that includes a p-channel metal-oxide-semiconductor (PMOS) transistor connected in parallel with the first NMOS transistor between the input and the output of the circuit.

12. The method of claim 11, wherein the plurality of switches are configured to drive the load using the NMOS amplification path at the first time based at least in part on a high linearity requirement at the first time.

13. The method of claim 11, wherein the plurality of switches are configured to drive the load using the CMOS amplification path at the second time based at least in part on a low current requirement or a low power consumption requirement at the second time.

14. The method of claim 11, further comprising:
configuring, at a third time, the plurality of switches to drive the load in the circuit using the NMOS amplification path with the first NMOS transistor switched off.

15. The method of claim 11, wherein the plurality of switches includes a switch, across an output capacitor, that is closed at the first time and open at the second time.

16. A circuit, comprising:
a first n-channel metal-oxide-semiconductor (NMOS) transistor in a first amplification path;
a p-channel metal-oxide-semiconductor (PMOS) transistor in a second amplification path;
a second NMOS transistor in the first amplification path and the second amplification path; and
a plurality of switches that are programmable to switch the PMOS transistor off in an NMOS mode and to switch the first NMOS transistor off in a complementary metal-oxide-semiconductor (CMOS) mode.

17. The circuit of claim 16, further comprising:
a neutralization circuit arranged to neutralize a nonlinear parasitic capacitance from the first NMOS transistor and the second NMOS transistor in the NMOS mode.

18. The circuit of claim 17, wherein the plurality of switches are further programmable to switch the PMOS transistor and the second NMOS transistor off in a sliced NMOS mode.

19. The circuit of claim 18, wherein the plurality of switches are programmable to drive a load in a signal path of a wireless receiver in the NMOS mode, the CMOS mode, or the sliced NMOS mode according to one or more of a current requirement or a linearity requirement.

20. The circuit of claim 18, wherein the plurality of switches are programmable to drive a load in a signal path of a wireless transmitter in the NMOS mode, the CMOS mode, or the sliced NMOS mode according to one or more of a current requirement or a linearity requirement.
